(19) United States
(12) Patent Application Publication
(10) Pub. No.: US 2024/0425362 A1
(43) Pub. Date: Dec. 26, 2024

(54) MICROMECHANICAL COMPONENT WITH EXTERNAL CONTACTING

(71) Applicant: Robert Bosch GmbH, Stuttgart (DE)

(72) Inventors: Benjamin Biasi, Stuttgart (DE); Timo Giesselmann, Stuttgart (DE)

(21) Appl. No.: 18/677,960

(22) Filed: May 30, 2024

(30) Foreign Application Priority Data
Jun. 21, 2023 (DE) 10 2023 205 803.0

(51) Int. Cl. B81B 7/00

(52) U.S. Cl. CPC B81B 7/008; B81B 2207/03; B81B 2207/07; B81B 2207/092

(57) ABSTRACT

A micromechanical component with an arrangement of external electrical contacts for contacting on a printed circuit board. The component is contactable in a first soldering configuration. The component is contactable in at least one second soldering configuration, and a calibration data set s configurable for the first soldering configuration or the second soldering configuration.

### CROSS REFERENCE

The present application claims the benefit under 35 U.S.C. § 119of German Patent Application No. DE 10 2023 205 803.0 filed on Jun. 21, 2023, which is expressly incorporated herein by reference in its entirety.

### BACKGROUND INFORMATION

The present invention proceeds from a micromechanical component with an arrangement of external electrical contacts for contacting on a printed circuit board, wherein the component is contactable in a first soldering configuration. Such components are generally described in the related art.

MEMS sensor units, such as the BMI270, serve to measure various physical quantities, for example acceleration and rotation rate in 3 axes each. They consist of a housing (FIG. 1) in which are integrated one or more MEMS chips as measuring elements and one or more ASICs as sensor data evaluation elements.

The ASICs inter alia include a sensor front end in order to convert the MEMS-characteristic physical quantities (e.g., capacitances) first into analog and then into digital values. Downstream of the sensor front end is a compensation unit whose task is to compensate for part-dependent and environment-dependent deviations (e.g., temperature) of the output data of the sensor front end and thus to achieve the accuracy of the output data of the MEMS sensor unit according to the specification (FIG. 6).

This compensation unit uses a set of calibration parameters that are ascertained as part of the manufacturing process and stored in a non-volatile memory (NVM) on the ASIC.

In this case, the MEMS sensor unit is contacted in a base and physical quantities (such as acceleration and rotation) are applied in order to measure the sensor and to determine calibration values. For example, calibration parameters for correcting the offset and sensitivity are determined and stored in the sensor unit.

The MEMS sensor unit is later soldered (FIG. 5) onto a circuit board, e.g., in the customer application, usually in the reflow method. According to the method, this introduces mechanical stresses into the housing, which can lead to a deviation in the sensor output signals. For example, offset and sensitivity may have different values after soldering. This behavior is characterized and quantified within the scope of product development and taken into account in the calibration so that the required accuracy values of the sensor are only available after soldering (so-called provisional calibration). According to the findings from a characterization, the calibration parameters are changed such that the sensor only achieves the optimum sensor accuracy after soldering.

In a new development of a sensor unit, the user is to be given the option to choose between a plurality of different soldering configurations during soldering. For example, only the external 14 pads may be soldered in a first configuration (FIG. 2), while pads further inside may be soldered in a second configuration 6 (FIG. 3). The user has the free choice to use one or the other configuration.

As described above, when soldering, mechanical stresses are introduced into the housing, and the size and nature of these stresses are also dependent on which of the soldering configurations has been chosen. However, this has the result that the above-described method of the provisional calibration can only be valid for one of the two configurations. If the other soldering configuration is chosen, the sensor is incorrectly and inaccurately calibrated.

### SUMMARY

An object of the present invention is to make the most accurate calibration for a plurality of different soldering configurations of a micromechanical component possible using the provisional calibration.

The present invention relates to a micromechanical component with an arrangement of external electrical contacts for contacting on a printed circuit board, wherein the component is contactable in a first soldering configuration. According to an example embodiment of the present invention, the component is contactable in at least one second soldering configuration, and a calibration data set is configurable for the first soldering configuration or the second soldering configuration.

According to an example embodiment of the present invention, there is a separate set of calibration parameters for each soldering configuration. The user is thus provided with a configuration option for operating the sensor. The user can configure the sensor according to the soldering configuration applied, and the corresponding set of calibration parameters can be used in the sensor.

An advantageous embodiment of the present invention provides that the component has an internal memory, in which a first calibration data set for the first soldering configuration or also a second calibration data set for the second soldering configuration is selectably stored.

Another advantageous embodiment of the present invention provides that the component has an internal memory, in which are stored a basic calibration data set as a first calibration data set for the first soldering configuration and difference values, in relation to the basic calibration data set, for determining a second calibration data set for the second soldering configuration.

Yet another advantageous embodiment of the present invention provides that the component has a type-specific or individual serial number, and a first calibration data set for the first soldering configuration and/or a second calibration data set for the second soldering configuration or also a difference value to a basic calibration data set is retrievably stored in an external database or a host processor in a manner assigned to the serial number.

An advantageous embodiment of the present invention provides that the component is configured to detect its soldering configuration automatically.

An advantage of the present invention is to make possible products that can be soldered onto the same circuit board interchangeably with already existing products. For example, for the IMUs (sensors for acceleration and rotation rate), the housing size of 2.5×3 mm² with 14 pads has been established across manufacturers. Since new products require additional pads for new functions, these pads can be placed in the free inner region of the pad layout and used for optional functions (see FIG. 2). This makes it possible for the user to use the same circuit board for a plurality of device variants or to continue to use an existing circuit board.

Examples of such optional functions are debugging interfaces for embedded microprocessors, reset input, further interfaces for connecting further sensors, external memories, or other peripheral components.

A further advantage of the present invention is to make the application of the sensors on inexpensive circuit boards possible. These circuit boards are characterized in that they comprise only a few (for example, one or two) wiring levels, and the signals from the inner pads cannot be connected or can only be connected with difficulty, since there is no way for the conductive paths. In this case, the functions of the optional inner pads may be omitted, and the inner pads may be left open.

### BRIEF DESCRIPTION OF THE DRAWINGS

FIG. 1 schematically shows a sensor package with soldering surfaces in the related art.

FIG. 2 schematically shows a sensor package with soldering surfaces in a first soldering configuration.

FIG. 3 schematically shows a sensor package with soldering surfaces in a second soldering configuration.

FIG. 4 schematically shows the sensor package, mounted on a printed circuit board, in the first soldering configuration.

FIG. 5 schematically shows the sensor package, mounted on a printed circuit board, in the second soldering configuration.

FIG. 6 schematically shows the structure of a MEMS sensor unit with calibration data in a non-volatile memory in the related art.

FIG. 7 schematically shows the structure of a MEMS sensor unit with two sets of calibration data in a non-volatile memory in a first embodiment example of the present invention.

### DETAILED DESCRIPTION OF EXAMPLE EMBODIMENTS

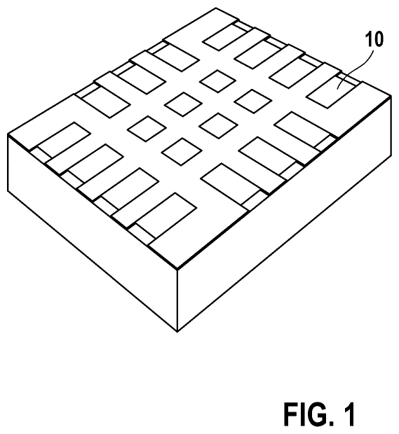

FIG. 1 schematically shows a sensor package with soldering surfaces in the related art. It shows a leadless package with an arrangement of external electrical contacts 10 for contacting on a printed circuit board.

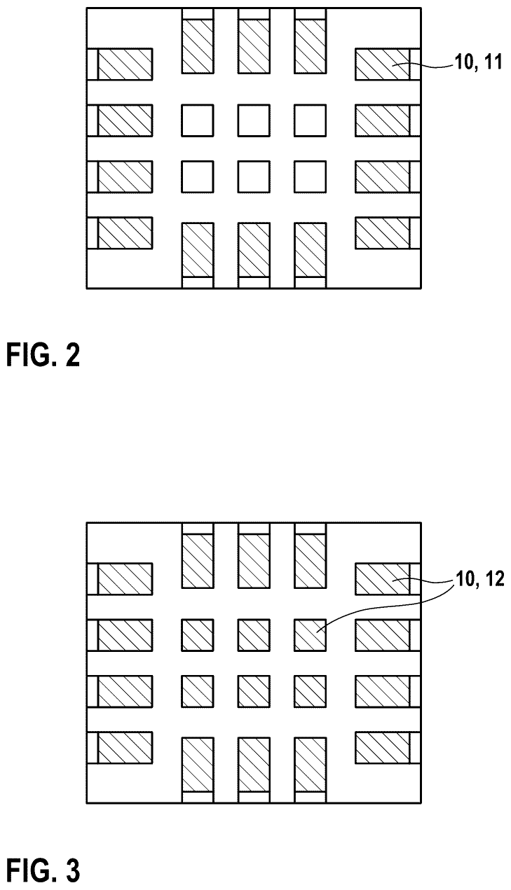

FIG. 2 schematically shows a sensor package with soldering surfaces in a first soldering configuration. It shows the bottom side of the leadless package of FIG. 1 with the arrangement of external electrical contacts 10, of which the shaded peripheral contacts are provided as a first soldering configuration 11 for contacting on a printed circuit board.

FIG. 3 schematically shows a sensor package with soldering surfaces in a second soldering configuration. It shows the bottom side of the leadless package of FIG. 1 with the arrangement of external electrical contacts 10, of which the shaded, all contacts are provided as a second soldering configuration 12 for contacting on a printed circuit board.

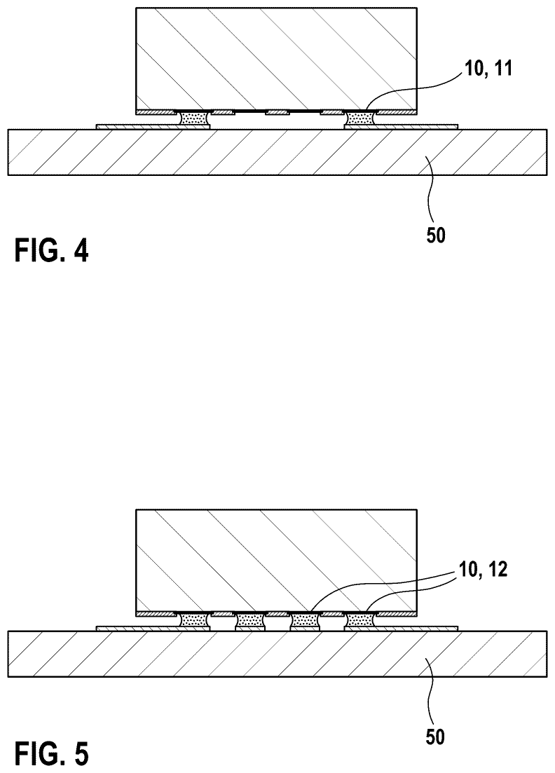

FIG. 4 schematically shows the sensor package, mounted on a printed circuit board 50, in the first soldering configuration 11. The printed circuit board can transfer forces to the micromechanical component via the peripheral solder contacts of the leadless package, which is why a calibration of the component must take into account the circumstances of the assembly.

FIG. 5 schematically shows the sensor package, mounted on a printed circuit board 50, in the second soldering configuration 12. The printed circuit board can transfer forces to the micromechanical component via all solder contacts of the leadless package, which is why a calibration of the component must take into account the circumstances of the assembly that have changed in comparison to FIG. 4.

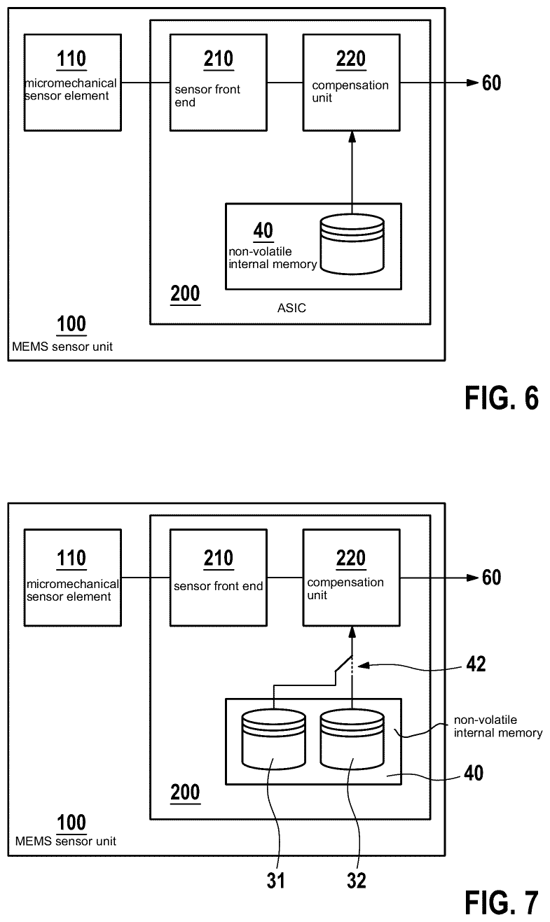

FIG. 6 schematically shows the structure of a MEMS sensor unit with calibration data in a non-volatile memory in the related art. Inside its package, a micromechanical component comprises a MEMS sensor unit 100 comprising a micromechanical sensor element 110. The signals of the sensor element are supplied to an ASIC 200 comprising an electronic signal input circuit, the sensor front end 210, and a compensation unit 220. The compensation unit obtains calibration information from a non-volatile internal memory 40. Calibration data are stored in the internal memory 40 for this purpose. Calibrated sensor signals 60 are output by the MEMS sensor unit 100.

FIG. 7 schematically shows the structure of a MEMS sensor unit with two sets of calibration data in a non-volatile memory in a first embodiment example of the present invention.

The MEMS sensor unit is constructed such that a plurality of different sets of calibration data can be stored in the non-volatile memory. The different sets of calibration data are assigned to the different soldering configurations. In contrast to the micromechanical component in FIG. 6, a first calibration data set 31 for the first soldering configuration and a second calibration data set 32 for the second soldering configuration are selectably stored in the internal memory 40 for this purpose. The compensation unit 220 is configurable with the first or second calibration data set, which is symbolized by the switch 42.

The MEMS sensor unit thus provides a configuration option, which can be used in the application to select the used soldering configuration. This configuration takes place by writing a register address when the MEMS sensor unit is initialized.

During the initialization of the MEMS sensor unit, for example after the power supply has been applied, the calibration data set assigned to the chosen soldering configuration is selected and is provided to the compensation unit for the compensation of the sensor signals.

The present invention can be realized in various embodiments.

In a second embodiment example, the configuration for selecting the calibration data set takes place by writing a storage cell in the non-volatile memory in the MEMS sensor unit once. In a third embodiment example, different calibration data sets for the soldering configurations are realized by adding difference values to a basic calibration data set, and the difference values are stored in the non-volatile memory. In a fourth embodiment example, the calibration data sets or difference values are not stored in the MEMS sensor unit but in a separate database. The appropriate set of difference values can be identified in the database on the basis of a part-specific, i.e., individual, serial number and then written in the application into the MEMS sensor unit, for example through register access.

In a fifth embodiment example, the difference values are characterized in a type-specific manner and are not calibrated in a part-specific manner. It is thus possible to work with fixed difference values, which may also be stored outside the non-volatile memory, for example in a host processor. For example, if it is determined in the characterization that an offset value between the first soldering configuration and the second soldering configuration always has a fixed offset of Δo with sufficient accuracy, the sensor can be calibrated for the first soldering configuration and, when the second soldering configuration is used, the offset Δo can be added to the sensor values in the host processor.

In a sixth embodiment example, the soldering configuration is ascertained by the MEMS sensor unit automatically, for example by carrying out a contact test on the optional contact pads. For example, the level of a pad equipped with a pull-up in the MEMS sensor unit may be determined. Depending on the soldering configuration, this pad may be externally connected to ground or open. Depending on the level at the pad when the sensor is started, the first soldering configuration or the second soldering configuration can be selected.

### List of Reference Signs

10 arrangement of external electrical contacts
11 first soldering configuration
12 second soldering configuration
20 internal memory
31 first calibration data set
32 second calibration data set
40 internal memory
42 switch
50 printed circuit board
60 calibrated sensor signal
100 MEMS sensor unit
110 MEMS sensor element
200 ASIC
210 sensor front end
220 compensation unit

What is claimed is:

1. A micromechanical component, comprising:
an arrangement of external electrical contacts for contacting on a printed circuit board, the component being contactable in a first soldering configuration, and the component is contactable in at least one second soldering configuration, wherein a calibration data set is configurable for the first soldering configuration or the second soldering configuration.

2. The micromechanical component according to claim 1, wherein the component includes an internal memory, in which a first calibration data set for the first soldering configuration and/or a second calibration data set for the second soldering configuration is selectably stored.

3. The micromechanical component according to claim 1, wherein the component includes an internal memory, in which are stored a basic calibration data set as a first calibration data set for the first soldering configuration and difference values, in relation to the basic calibration data set, for determining a second calibration data set for the second soldering configuration.

4. The micromechanical component according to claim 1, wherein the component has a type-specific or individual serial number, and a first calibration data set for the first soldering configuration and/or a second calibration data set for the second soldering configuration and/or a difference value to a basic calibration data set is retrievably stored in an external database or a host processor in a manner assigned to the serial number.

5. The micromechanical component according to claim 1, wherein the component is configured to automatically detect its soldering configuration.
